(19) United States
(12) Patent Application Publication
(10) Pub. No.: US 2024/0397468 A1
(43) Pub. Date: Nov. 28, 2024

(54) DEVICES AND METHODS FOR TARGET END DEVICES POSITIONING

(71) Applicant: Nokia Solutions and Networks Oy, Espoo (FI)

(72) Inventors: Oana-Elena BARBU, Aalborg (DK); Diomidis MICHALOPOULOS, Munich (DE)

(21) Appl. No.: 18/688,044

(22) PCT Filed: Sep. 9, 2021
(86) PCT No.: PCT/EP2021/074804

§ 371 Date: Feb. 29, 2024

(51) Int. Cl. H04W 64/00

(52) U.S. Cl. CPC H04W 64/00

(57) ABSTRACT

A positioning reports producer (101) comprising: —means for receiving one or more reference signals for positioning a target end device; —means for receiving a set of trained parameters defining a training-based compression algorithm, the set of trained parameters being obtained by a joint training of the training-based compression algorithm and one or more training-based algorithms implemented in a positioning reports consumer (102); —means for generating a compressed positioning report by running the training-based compression algorithm; and —means for sending the compressed positioning report to the positioning reports consumer (102).

### TECHNICAL FIELD

Various example embodiments are related generally to devices, methods, and computer program products for target end devices positioning in wireless networks.

### BACKGROUND

Positioning techniques have been initially introduced in cellular networks to meet regulatory requirements of emergency calls positioning. Since then, positioning services have been widely developed and supported in the different mobile radio generations to provide indoor and outdoor/uplink and downlink positioning of end devices.

In the 3^{rd} Generation Partnership Project (3GPP), several working groups develop specifications for positioning end devices in cellular networks. These specifications define positioning techniques, signals, measurements, procedures and architectures to meet positioning performance requirements for a plethora of commercial and industrial use cases. The positioning performance requirements are generally defined in terms of accuracy, latency, availability, integrity, and reliability. The latest specifications in Release 16 and Release 17 relate to the positioning features for 5G networks.

Release 16 specifies the positioning architecture, signals and measurements for the 5G new radio (NR) which are derived from the positioning features for the 4G (for Long Term Evolution networks). In Release 17, study enhancements and solutions necessary to support 5G commercial and industrial use case requirements are addressed.

The main positioning performance requirements relevant to the latest studies in 3GPP are the positioning accuracy and latency required to support 5G industrial use cases (e.g. logistics, autonomous vehicles, localized sensing, Internet of Thing (IoT) applications) and 5G end devices (e.g. IoT devices, robots, sensors, drones). In particular, high positioning accuracy down to the meter is required for general 5G commercial use cases and high positioning accuracy down to decimeter is required for example for IoT use cases. For the positioning latency, the target latency requirement for general use cases is lower than 100 ms and is in the order of 10 ms for IoT use cases.

For positioning a target end device, positioning information is sent, during a positioning session, from a positioning reports producer to a positioning reports consumer. The positioning reports producer generates a positioning report from positioning measurements and sends the positioning report to the positioning reports consumer that estimates a location of the target end device from the positioning report. The size of the positioning report is limited to a maximum packet size which is in general specified by the positioning reports consumer at the beginning of the positioning session. Thus, in order to send a large size positioning report, the positioning report producer has to split the positioning report into several messages and send them sequentially to the positioning reports consumer.

Given the positioning accuracy and latency requirements, the positioning session is either latency sensitive or accuracy sensitive. Thus, for a positioning session constrained by the latency or accuracy requirements, the positioning reports producer would need to decide to either compress the positioning report to reduce its size, which induces reducing the positioning accuracy, or to send the large report over a large number of messages, which incurs unacceptable latency cost.

There is accordingly a need for enhanced positioning techniques for sending positioning information while meeting positioning accuracy and latency requirements.

### SUMMARY

The scope of protection is set out by the independent claims. The embodiments, examples and features, if any, described in this specification that do not fall under the scope of the protection are to be interpreted as examples useful for understanding the various embodiments or examples that fall under the scope of protection.

In a first aspect, there is provided a positioning reports producer comprising means for receiving one or more reference signals for positioning a target end device, means for receiving a set of trained parameters defining a training-based compression algorithm from a training device, the set of trained parameters being obtained by a joint training of the training-based compression algorithm and one or more training-based algorithms implemented in a positioning reports consumer, means for generating a compressed positioning report by running the training-based compression algorithm, the training-based compression algorithm taking as input data derived from the one or more reference signals and generating as output the compressed positioning report, and means for sending the compressed positioning report to the positioning reports consumer.

In a second aspect, there is provided a positioning reports consumer comprising means for receiving a compressed positioning report from a positioning reports producer, means for receiving, from a training device, a set of trained parameters defining a training-based decompression algorithm and a set of trained parameters defining a training-based distance correction algorithm, the sets of trained parameters being obtained by a joint training of the training-based decompression algorithm, the training-based distance correction algorithm and a training-based compression algorithm implemented in the positioning reports producer, means for generating a decompressed positioning report by running the training-based decompression algorithm, the training-based decompression algorithm taking as input the compressed positioning report and generating as output the decompressed positioning report, and means for generating an estimated distance for positioning a target end device by running the training-based distance correction algorithm, the estimated distance designating a distance separating the target end device and a transmitter or a receiver of one or more reference signals for positioning the target end device, the training-based distance correction algorithm taking as input reconstructed data derived from the decompressed positioning report and generating as output the estimated distance.

In a third aspect, there is provided a training device comprising means for generating a first set of trained parameters defining a training-based compression algorithm, a second set of trained parameters defining a training-based decompression algorithm, and a third set of trained parameters defining a training-based distance correction algorithm. The first set of trained parameters, the second set of trained parameters and the third set of trained parameters being generated by performing a joint training of the compression, decompression and the distance correction training-based algorithms using training data and according to a minimization of a loss function.

In an embodiment, the joint training of the compression, decompression and distance correction training-based algorithms comprises jointly training a training-based compression algorithm to generate a training compressed positioning report from data derived from one or more training reference signals for positioning a training target end device, for a given training compression level, training a training-based decompression algorithm to generate a training decompressed positioning report from the training compressed positioning report, training a training-based distance correction algorithm to generate a training estimated distance for positioning the training target end device from reconstructed data derived from the training decompressed positioning report, and computing a training distance estimation error by applying the loss function to the training estimated distance and a training real distance separating the training target end device from a training transmitter or a training receiver of the one or more training reference signals.

In an embodiment, the training-based compression algorithm and the training-based decompression algorithm form an autoencoder of a given code size that maps to a given compression level, the autoencoder comprising the training-based compression algorithm as an encoder and the training-based decompression algorithm as a decoder.

In an embodiment, the given code size is selected from a set of two or more code sizes as a tradeoff between positioning latency and accuracy.

In an embodiment, the two or more code sizes map to two or more compression levels, the joint training being performed for the two or more compression levels, the first set of trained parameters, the second set of trained parameters, and the third set of trained parameters being generated for the two or more code sizes.

In an embodiment, the training device further comprises means for sending the first set of trained parameters to a positioning reports producer and sending the second set of trained parameters and the third set of trained parameters to a positioning reports consumer.

In a fourth aspect, there is provided a location management function implementing the positioning reports consumer of any preceding feature.

In a sixth aspect, there is provided a target end device implementing the positioning reports producer of any preceding feature, the received one or more reference signals being downlink reference signals for positioning the target end device received from an access network entity in a wireless communication network.

In a seventh aspect, there is provided an access network entity for use in a wireless communication network, the access network entity implementing the positioning reports producer of any preceding feature, the received one or more reference signals being uplink reference signals for positioning the target end device received from the target end device.

In an embodiment, the positioning report comprises data for positioning the target end device, the data for positioning the target end device comprising measurements for positioning the target end device or signal features related to the one or more reference signals or raw signal samples comprised in the one or more reference signals.

In an embodiment, the training-based compression algorithm is a neural network defined by a set of parameters comprising weight values and bias values.

In an embodiment, the training-based decompression algorithm is a neural network defined by a set of parameters comprising weight values and bias values.

In an embodiment, the training-based distance correction algorithm is a neural network defined by a set of parameters comprising weight values and bias values.

In an eighth aspect, there is provided a method for generating and sending a compressed positioning report comprising receiving one or more reference signals for positioning a target end device, receiving, from a training device, a set of trained parameters defining a training-based compression algorithm, the set of trained parameters being obtained by a joint training of the training-based compression algorithm and one or more training-based algorithms implemented in a positioning reports consumer, generating a compressed positioning report by implementing the training-based compression algorithm, the training-based compression algorithm taking as input data derived from the one or more reference signals and generating as output the compressed positioning report, and sending the compressed positioning report to the positioning reports consumer.

In a ninth aspect, there is provided a method for generating an estimated distance for positioning a target end device comprising receiving a compressed positioning report from a positioning reports producer, receiving, from a training device, a set of trained parameters defining a training-based decompression algorithm and a set of trained parameters defining a training-based distance correction algorithm, the sets of trained parameters being obtained by a joint training of the training-based decompression algorithm, the training-based distance correction algorithm and a training-based compression algorithm implemented in the positioning reports producer, generating a decompressed positioning report by implementing the training-based decompression algorithm, the training-based decompression algorithm taking as input the compressed positioning report and generating as output the decompressed positioning report, generating an estimated distance for positioning a target end device by implementing the training-based distance correction algorithm, the estimated distance designating a distance separating the target end device and a transmitter or a receiver of one or more reference signals for positioning the target end device, the training-based distance correction algorithm taking as input reconstructed data derived from the decompressed positioning report and generating as output the estimated distance.

In a tenth aspect, there is provided a method for joint training three training-based algorithms comprising generating a first set of trained parameters defining a training-based compression algorithm, a second set of trained parameters defining a training-based decompression algorithm, a third set of trained parameters defining a training-based distance correction algorithm, the first set of trained parameters, the second set of trained parameters and the third set of trained parameters being generated by performing a joint training of the compression, decompression and distance correction training-based algorithms using training data and according to a minimization of a loss function.

In an eleventh aspect, there is provided a non-transitory computer-readable medium storing computer-executable instructions that, when executed by at least one processor at an apparatus, cause the apparatus to perform a method for generating and sending a compressed positioning report according to any preceding feature.

Generally, the computer-executable instructions cause the apparatus to perform one or more or all steps of the method for generating and sending a compressed positioning report as disclosed herein.

In a twelfth aspect, there is provided a non-transitory computer-readable medium storing computer-executable instructions that, when executed by at least one processor at an apparatus, cause the apparatus to perform a method for generating an estimated distance for positioning a target end device according to any preceding feature.

Generally, the computer-executable instructions cause the apparatus to perform one or more or all steps of the method for generating an estimated distance for positioning a target end device as disclosed herein.

In a thirteenth aspect, there is provided a non-transitory computer-readable medium storing computer-executable instructions that, when executed by at least one processor at an apparatus, cause the apparatus to perform a method for joint training three training-based algorithms according to any preceding feature.

Generally, the computer-executable instructions cause the apparatus to perform one or more or all steps of the method for joint training three training-based algorithms as disclosed herein.

Generally, the positioning reports producer comprises means for performing one or more or all steps of the method for generating and sending a compressed positioning report as disclosed herein. The means include circuitry configured to perform one or more or all steps of the method for generating and sending a compressed positioning report as disclosed herein. The means may include at least one processor and at least one memory including computer program code, wherein the at least one memory and the computer program code are configured to, with the at least one processor, cause the positioning reports producer to perform one or more or all steps of the method for generating and sending a compressed positioning report as disclosed herein.

Generally, the positioning reports consumer comprises means for performing one or more or all steps of the method for generating an estimated distance for positioning a target end device as disclosed herein. The means include circuitry configured to perform one or more or all steps of the method for generating an estimated distance for positioning a target end device as disclosed herein. The means may include at least one processor and at least one memory including computer program code, wherein the at least one memory and the computer program code are configured to, with the at least one processor, cause the positioning reports consumer to perform one or more or all steps of the method for generating an estimated distance for positioning a target end device as disclosed herein.

Generally, the training device comprises means for performing one or more or all steps of the method for joint training three training-based algorithms as disclosed herein. The means include circuitry configured to perform one or more or all steps of the method for joint training three training-based algorithms as disclosed herein. The means may include at least one processor and at least one memory including computer program code, wherein the at least one memory and the computer program code are configured to, with the at least one processor, cause the training device to perform one or more or all steps of the method for joint training three training-based algorithms as disclosed herein.

In a fourteenth aspect, there is provided a positioning reports producer comprising at least one processor and at least one memory including computer program code. The at least one memory and the computer program code are configured to, with the at least one processor, cause the positioning reports producer to receive one or more reference signals for positioning a target end device, receive a set of trained parameters defining a training-based compression algorithm from a training device, the set of trained parameters being obtained by a joint training of the training-based compression algorithm and one or more training-based algorithms implemented in a positioning reports consumer, generate a compressed positioning report by running the training-based compression algorithm, the training-based compression algorithm taking as input data derived from the one or more reference signals and generating as output the compressed positioning report, send the compressed positioning report to the positioning reports consumer.

In a fifteenth aspect, there is provided a positioning reports consumer comprising at least one processor and at least one memory including computer program code. The at least one memory and the computer program code are configured to, with the at least one processor, cause the positioning reports consumer to receive a compressed positioning report from a positioning reports producer, receive, from a training device, a set of trained parameters defining a training-based decompression algorithm and a set of trained parameters defining a training-based distance correction algorithm, the sets of trained parameters being obtained by a joint training of the training-based decompression algorithm, the training-based distance correction algorithm and a training-based compression algorithm implemented in the positioning reports producer, generate a decompressed positioning report by running the training-based decompression algorithm, the training-based decompression algorithm taking as input the compressed positioning report and generating as output the decompressed positioning report, generate an estimated distance for positioning a target end device by running the training-based distance correction algorithm, the estimated distance designating a distance separating the target end device and a transmitter or a receiver of one or more reference signals for positioning the target end device, the training-based distance correction algorithm taking as input reconstructed data derived from the decompressed positioning report and generating as output the estimated distance.

In a sixteenth aspect, there is provided a training device comprising at least one processor and at least one memory including computer program code. The at least one memory and the computer program code are configured to, with the at least one processor, cause the training device to generate a first set of trained parameters defining a training-based compression algorithm; a second set of trained parameters defining a training-based decompression algorithm; a third set of trained parameters defining a training-based distance correction algorithm; the first set of trained parameters, the second set of trained parameters and the third set of trained parameters being generated by performing a joint training of the compression, decompression and the distance correction training-based algorithms using training data and according to a minimization of a loss function.

In an embodiment, the at least one memory and the computer program code are configured to, with the at least one processor, cause the training device to send the first set of trained parameters to a positioning reports producer and send the second set of trained parameters and the third set of trained parameters to a positioning reports consumer.

### BRIEF DESCRIPTION OF THE DRAWINGS

The accompanying drawings, which are incorporated in and constitute a part of this specification, illustrate example embodiments together with the general description given above, and the detailed description given below.

FIG. 1 is a schematic diagram illustrating an exemplary wireless network in which exemplary embodiments may be implemented.

FIG. 2 is a block diagram illustrating the structure of a positioning reports producer, a positioning reports consumer and a training device, according to some embodiments.

FIG. 3A is a block diagram illustrating the structure of a positioning reports producer, according to a first embodiment.

FIG. 3B is a block diagram illustrating the structure of a positioning reports consumer, according to the first embodiment.

FIG. 4A is a block diagram illustrating the structure of a positioning reports producer, according to a second embodiment.

FIG. 4B is a block diagram illustrating the structure of a positioning reports consumer, according to the second embodiment.

FIG. 5A is a block diagram illustrating the structure of a positioning reports producer, according to a third embodiment.

FIG. 5B is a block diagram illustrating the structure of a positioning reports consumer, according to the third embodiment.

FIG. 6 is a flowchart illustrating a method for generating and sending a compressed positioning report, according to some embodiments.

FIG. 7 is a flowchart illustrating a method for generating an estimated distance for positioning a target end device, according to some embodiments.

FIG. 8 is a flowchart illustrating a method for training three training-based algorithms, according to some embodiments.

FIG. 9 is a block diagram illustrating an exemplary structure of a network entity operable in a wireless network, according to some embodiments.

It should be noted that these figures are intended to illustrate the general characteristics of devices, methods, and structures utilized in certain example embodiments and to supplement the written description provided below. These drawings are not, however, to scale and may not precisely reflect the precise structural or performance characteristics of any given embodiment and should not be interpreted as defining or limiting the range of values or properties encompassed by example embodiments. The use of similar or identical reference numbers in the various drawings is intended to indicate the presence of a similar or identical element or feature.

### DETAILED DESCRIPTION

Detailed example embodiments are disclosed herein. However, specific structural and functional details disclosed herein are merely representative for purposes of describing example embodiments. The example embodiments may, however, be embodied in many alternate forms and should not be construed as limited to only the embodiments set forth herein. Accordingly, while example embodiments are capable of various modifications and alternative forms, the embodiments are shown by way of example in the drawings and will be described herein in detail. It should be understood, however, that there is no intent to limit example embodiments to the particular forms disclosed.

Specific details are provided in the following description to provide a thorough understanding of example embodiments. However, it will be understood by one of ordinary skill in the art that example embodiments may be practiced without these specific details. For example, systems may be shown in block diagrams so as not to obscure the example embodiments in unnecessary detail. In other instances, well-known processes, structures and techniques may be shown without unnecessary detail in order to avoid obscuring example embodiments.

The various embodiments provide devices, methods, and computer program products for positioning a target end device operable in a wireless network.

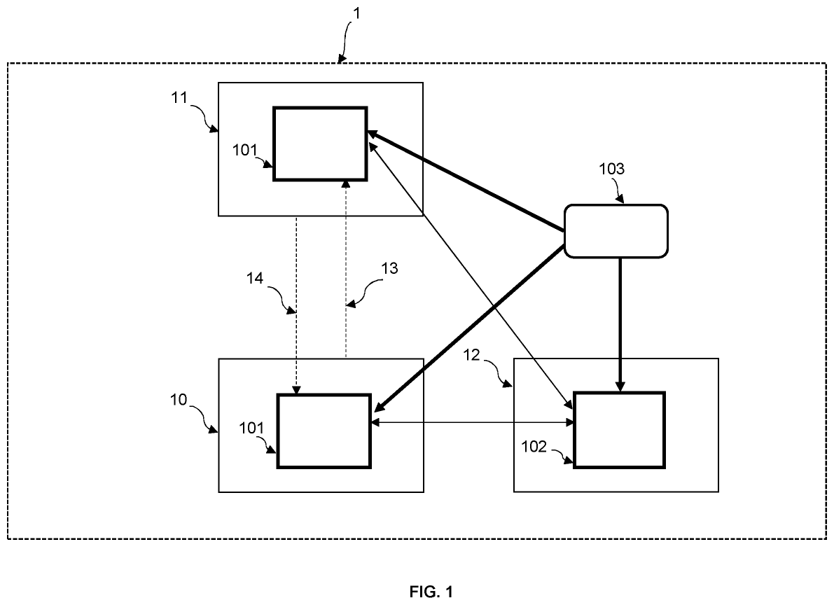

FIG. 1 is a block diagram of an exemplary application for positioning a target end device 10 operable in a wireless network 1.

The positioning architecture depicted in FIG. 1 involves the target end device 10, a network device 11, and a location server 12. The target end device 10 communicates with the network device 11 in uplink and downlink through a wireless transmission channel.

Data/signals/messages sent from the target end device 10 to the network device 11 correspond to uplink communications. Data/signals/messages sent from the network device 11 to the target end device 10 correspond to downlink communications.

The positioning architecture illustrates the network entities operable in the wireless network 1 and involved in the uplink positioning and the downlink positioning of the target end device 10. More specifically:
uplink positioning of the target end device 10 involves a positioning reports producer 101 implemented at the network device 11 and a positioning reports consumer 102 implemented at the location server 12;
downlink positioning of the target end device 10 involves a positioning reports producer 101 implemented at the target end device 10 and the positioning reports consumer 102 implemented at the location server 12.

The wireless network 1 may be any wireless network involving any type of wireless propagation medium adapted to wireless connectivities. Exemplary wireless networks comprise, without limitations, ad-hoc wireless networks, mobile ad-hoc networks, wireless local area networks, wireless sensor networks, radio broadcasting networks and radio communication networks (e.g. LTE, LTE-advanced, 4G/5G and beyond).

The target end device 10 may be any fixed or mobile device/system/object provided with the required hardware and/or software technologies enabling wireless communications and transfer of data and/or signals and/or messages to the network device 10 and the location server 12. The target end device 10 may be remotely monitored and/or controlled. The target end device 10 may be equipped with one or more transmit antennas and one or more receive antennas.

Exemplary target end devices comprise, without limitations, mobile phones, laptops, tablets, robot, drones, sensors, wearables, Machine-to-Machine devices, IoT devices, Vehicle-to-everything devices (e.g. vehicles, infrastructure connected devices).

The network device 11 may be any device configured to operate in a wireless network to serve one or more end devices. The network device 11 may be equipped with one or more transmit antennas and one or more receive antennas.

Exemplary network devices 11 comprise, without limitation:
radio access network entities such as base stations (e.g. cellular base stations like eNodeB in LTE and LTE-advanced networks and gNodeB used in 5G networks, and femtocells used at homes or at business centers);
control stations (e.g. radio network controllers, base station controllers, network switching sub-systems);
relay stations, and
access points in local area networks or ad-hoc networks.

Exemplary applications of the wireless network 100 comprise:
Machine-To-Machine (M2M);
Device-To-Device (D2D);
Industry 4.0;
IoT (for example vehicle-to-everything communications) involving networks of physical devices, machines, vehicles, home alliances and many other objects connected to each other and provided with a connectivity to the Internet and the ability to collect and exchange data without requiring human-to-human or human-to-computer interactions.

Exemplary wireless technologies used in IoT applications comprise:
short range wireless networks (e.g. Bluetooth mesh networking, Light-Fidelity, Wi-Fi™, and Near-Field communications);
medium range wireless networks (e.g. LTE-advanced, Long Term Evolution-Narrow Band, NarrowBand IoT), and
long range wireless networks (e.g. Low-Power Wide Area Networks (LPWANs), Very small aperture terminal, and long-range Wi-Fi™ connectivity).

Exemplary applications of M2M and IoT applications comprise, without limitation:
consumer applications (e.g. Internet of Vehicles, home automation, smart cities, wearable technologies, and connected health), and
commercial applications (e.g. digitalized healthcare connecting medical resources and healthcare services in which special monitors and sensors may be used to enable remote health monitoring and emergency notifications, smart traffic control, and road assistance).

During an uplink positioning session, the positioning reports consumer 102 requests an uplink positioning report from the positioning reports producer 101 implemented at the network device 11. The uplink positioning is performed using one or more uplink reference signals 13 for positioning the target end device 10. The one or more uplink reference signals are transmitted by the target end device 10 to the network device 11. The positioning reports producer 101 generates a compressed uplink positioning report from the one or more uplink reference signals and sends the compressed uplink positioning report to the positioning reports consumer 102. The positioning reports consumer 102 processes the received compressed uplink positioning report to generate an estimated distance separating the target end device 10 and the network device 11 (which is the receiver of the one or more uplink reference signals 13 during uplink positioning).

During a downlink positioning session, the positioning reports consumer 102 requests a downlink positioning report from the positioning reports producer 101 implemented at the target end device 10. The downlink positioning is performed using one or more downlink reference signals 14 for positioning the target end device 10. The one or more downlink reference signals 14 are sent by the network device 11 to the target end device 10. The positioning reports producer 101 implemented at the target end device 10 generates a compressed downlink positioning report from the one or more downlink reference signals 14 and sends the compressed downlink positioning report to the positioning reports consumer 102. The positioning reports consumer 102 processes the received compressed positioning report to generate an estimated distance separating the target end device 10 and the network device 11 (which is the transmitter of the one or more downlink reference signals 14 during downlink positioning).

In general, during a positioning session (downlink or uplink) of the target end device 10, positioning is performed using one or more reference signals (downlink or uplink) for positioning the target end device 10 that are transmitted or received by the network device 11 to or from the target end device 10. During the positioning session, the positioning reports producer 101 (implemented at the target end device 10 in downlink positioning or at the network device 11 in uplink positioning) generates a compressed positioning report from the one or more reference signals and sends the compressed positioning report to the positioning reports consumer 102. The positioning reports consumer 102 generates a decompressed positioning report from the received compressed positioning reports and processes the decompressed positioning report to generate an estimated distance separating the target end device 10 and the network device 11 (which is the transmitter or the receiver of the one or more reference signals). The positioning reports consumer 102 sends the estimated distance to the location server 12 for further processing in order to generate a localization or a position of the target end device 10. The location server 12 may use other input data for localizing the target end device 10 such as positioning data sent by one or more positioning systems such as satellite positioning systems (e.g. the Global Navigation Satellite System or GNSS and the Global Positioning System or GPS).

In application to 5G networks, the network device 11 may be a radio access network entity (for example a next generation-eNB or a gNB) which implements transmission reception points that are configured to transmit or to receive the one or more reference signals for positioning the target end device 10. In this application, the positioning reports consumer 102 may be or may be implemented as a part of a location management function operable in the 5G core network. In downlink positioning, the positioning reports producer 101 and the positioning reports consumer 102 may communicate over the LTE Positioning Protocol (LPP) interface. In uplink positioning, the positioning reports producer 101 and the positioning reports consumer 102 may communicate over the Network Radio Positioning Protocol annex (NRPPa) interface.

For example, for target end device-assisted positioning, the positioning reports producer 101 is implemented as a part of the target end device 10 and the positioning reports consumer 102 is implemented as a part of the localization management function and for target end device-based positioning, the positioning reports producer 101 and the positioning reports consumer 102 are implemented as parts of the target end device 10.

The one or more reference signals for positioning the target end device 10 comprise positioning reference signals and non-positioning signals that can be used for positioning the target end device 10. Positioning reference signals refer to reference signals that are specific to the positioning task. Non-positioning reference signals refer to reference signals that are specific to other tasks but can be exploited for the positioning task.

For example, the non-positioning reference signals comprise, without limitation, mobility reference signals and radio resource management reference signals (e.g. channel state information reference signals and synchronization reference signals).

For example, the positioning reference signals comprise:
downlink positioning reference signals (DL-PRS), and
uplink sounding reference signals (UL-SRS) such as the UL-SRS specified in 3GPP Release 17.

The positioning reports producer 101 generates the compressed positioning report by applying a compression algorithm. The positioning reports consumer 102 generates the decompressed positioning report by applying a decompression algorithm and generates the estimated distance from the decompressed positioning report by applying a distance correction algorithm.

The compression of the positioning reports according to the various embodiments relies on implementing a training-based compression algorithm at the positioning reports producer 101. The processing of the compressed positioning reports relies on implementing a training-based decompression algorithm and a training-based distance correction algorithm at the positioning reports consumer 102 such that the training-based compression algorithm, the training-based decompression algorithm and the training-based distance correction algorithm are trained jointly.

The training-based compression, decompression, and distance correction algorithms are for example supervised artificial intelligence/machine learning algorithms/models.

Exemplary supervised artificial intelligence/machine learning algorithms/models comprise, without limitation, support vector machines, linear regression algorithms, logistic regression algorithms, naive Bayes algorithms, linear discriminant analysis, decision trees, K-nearest neighbor algorithm, neural networks, and similarity learning.

Since the training-based compression algorithm, the training-based decompression algorithm and the training-based distance correction algorithm are implemented in network entities that are not collocated, the training of the three algorithms is performed, according to the various embodiments, in a central way at a training device that is external to the positioning reports producer 101 and the positioning reports consumer 102.

Accordingly, the wireless network 1 further comprises a training device 103 comprising:
means for communicating with the positioning reports producer 101 (implemented at the network device 11 or at the target end device 10) for the operations related to the training of the training-based compression algorithm, and
means for communicating with the positioning reports consumer 12 for the operations related to the training of the training-based decompression algorithm and the training-based distance correction algorithm.

For example, the training device 103 is implemented as a part of a network management entity or a positioning management entity operable in the wireless network 1.

In application to 5G and beyond networks, the training device 103 may be implemented at a central network entity such as the access and mobility management function (AMF) or the localization management function (LMF).

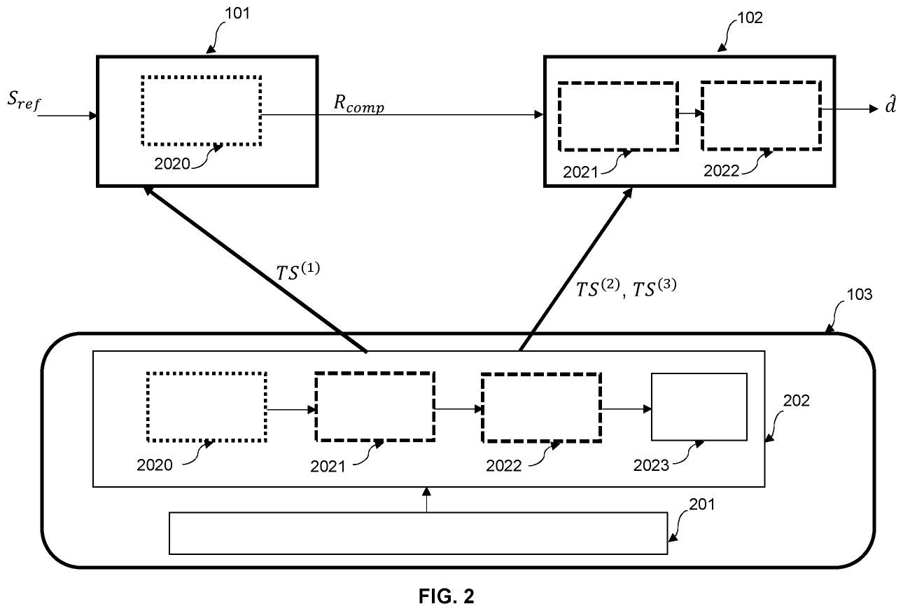

FIG. 2 is block structure illustrating the processing at the positioning reports producer 101, the positioning reports consumer 102 and the training device 103 during a positioning session that may be an uplink or a downlink positioning session. The training performed at the training device 103 is performed offline, before the triggering of the positioning session by the positioning reports consumer 102.

The positioning reports producer 101 comprises a compression unit 2020 that implements a training-based compression algorithm. The training-based compression algorithm is a compression algorithm that is defined by a set of trainable parameters that are trained using training data through a training process during which the training-based compression algorithm is trained to generate output data from input data. Once trained, the training-based compression algorithm defined by the set of trained parameters, is run to generate a compressed positioning report denoted by R_{comp} from one or more reference signals denoted by S_{ref} for positioning the target end device 10.

The positioning reports consumer 102 comprises a decompression unit 2021 that implements a training-based decompression algorithm and a distance calculation unit 2022 that implements a training-based distance correction algorithm.

The training-based decompression algorithm is a decompression algorithm defined by a set of trainable parameters that are trained using training data through a training process during which the decompression algorithm is trained to generate output data from input data. Once trained, the training-based decompression algorithm, defined by the set of trained parameters, is run to generate a decompressed positioning report denoted by R_{dec} from the compressed positioning report R_{comp}.

The training-based distance correction algorithm is a data processing algorithm that is defined by a set of trainable parameters that are trained using training data though a training process during which the distance correction algorithm is trained to generate output data from input data. Once trained, the training-based distance correction algorithm, defined by the set of trained parameters, is run to generate an estimated distance denoted by & from reconstructed data derived from the decompressed positioning report R_{dec}.

The training device 103 comprises a training data generation unit 201 configured to generate training data and a training unit 202 configured to perform the training of the training-based compression, decompression, and distance correction algorithms.

In order to perform the joint training of the three training-based algorithms in a centralized way, the training unit 202 comprises identical structures of the compression unit 2020, the decompression unit 2021 and the distance correction unit 2022. More specifically, the training unit 202 comprises:
a compression unit 2020 that is identical to the compression unit 2020 implemented in the positioning reports producer 101 such that the compression unit 2020 implements the same training-based compression algorithm as implemented in the positioning reports producer 101;
a decompression unit 2021 that is identical to the decompression unit 2021 comprised in the positioning reports consumer 102 such that the decompression unit 2021 implements the same training-based decompression algorithm as implemented in the positioning reports consumer 102;
a distance correction unit 2022 that is identical to the distance correction unit 2022 comprised in the positioning reports consumer 102 such that the distance correction unit 2021 implements the same training-based distance correction algorithm as implemented in the positioning reports consumer 102.

The joint training performed by the training unit 202 consists in generating:
a first set of trained parameters denoted by TS⁽¹⁾ defining the training-based compression algorithm;
a second set of trained parameters denoted by TS⁽²⁾ defining the training-based decompression algorithm, and
a third set of trained parameters denoted by TS⁽³⁾ defining the training-based distance correction algorithm.

The training unit 202 is configured to generate the first set of trained parameters TS⁽¹⁾, the second set of trained parameters TS⁽²⁾ and the third set of trained parameters TS⁽³⁾ by performing a joint training of the training-based compression, decompression and distance correction algorithms using the training data generated by the training data generation unit 201 according to the minimization of a loss function denoted by L(.). The loss function is used by a loss function calculation unit 2023 comprised in the training unit 202 and configured to evaluate a training error using the loss function L(.).

More specifically, the joint training of the three training-based algorithms comprises:
training the training-based compression algorithm to generate a training compressed positioning report denoted by R_{comp}^{(t)} from data derived from one or more training reference signals denoted by S_{ref}^{t}, for positioning a training target end device for a training compression level;
training the training-based decompression algorithm to generate a training decompressed positioning report denoted by R_{dec}^{(t)} from the training compressed positioning report R_{comp}^{(t)};
training the training-based distance correction algorithm to generate a training estimated distance denoted by \hat{d}ₜ for positioning the training target end device from reconstructed data derived from the training decompressed positioning report R_{dec}^{(t)}, and
computing, by the loss function calculation unit 2023, a training error (also referred to as ‘training distance estimation error’) by applying the loss function L(.) to the training estimated distance \hat{d}ₜ and a training real distance denoted by dₜ separating the training target end device and a training transmitter or receiver of the one or more training reference signals S_{ref}^{(t)}.

The sets of trained parameters TS⁽¹⁾, TS⁽²⁾, and TS⁽³⁾ generated at the end of the training process correspond to the set of parameters that enable the minimization of the training error.

Once determined the sets of trained parameters TS⁽¹⁾, TS⁽²⁾, and TS⁽³⁾, the training device 103 sends the set of trained parameters TS⁽¹⁾ to the positioning reports producer 101 and sends the set of trained parameters TS⁽²⁾, and TS⁽³⁾ to the positioning reports consumer 102.

In application to 5G and beyond networks, the transmission of the sets of trained parameters may be performed using control channels such as the N1 interface and the NLs interfaces when the training device 103 is implemented in the access and mobility function.

Once receiving the set of trained parameters TS⁽¹⁾, the positioning reports producer 101 generates a compressed positioning report R_{comp} from the one or more reference signals S_{ref} by running the training-based compression algorithm defined by the first set of trained parameters TS⁽¹⁾. The training-based compression algorithm takes as input the one or more reference signals S_{ref} for positioning the target end device 10 and generates as output the compressed positioning report R_{comp}. Then, the positioning reports producer 101 sends then the compressed positioning report R_{comp} to the positioning reports consumer 102.

The positioning reports consumer 102 receives accordingly the compressed positioning report R_{comp} from the positioning reports producer 101 and receives the second set of trained parameters TS⁽²⁾ defining the training-based decompression algorithm and the third set of trained parameters TS⁽³⁾ defining the training-based distance correction algorithm from the training device 103.

The compression unit 2021 comprised in the positioning reports consumer 102 is configured to generate a decompressed positioning report R_{dec} by running the training-based decompression algorithm, the training-based decompression algorithm taking as input the compressed positioning report R_{comp} and generating as output a decompressed positioning report denoted by R_{dec}.

The distance calculation unit 2022 comprised in the positioning reports consumer 102 is configured to generate an estimated distance \hat{d} for positioning the target end device 10 by running the training-based distance correction algorithm that takes as input reconstructed data derived from the decompressed positioning report R_{dec} and generates as output the estimated distance \hat{d}. The estimated distance \hat{d} designates a distance separating the target end device and the transmitter or receiver of the one or more reference signals S_{ref}.

The training data generation unit 201 generates training data and provides the training data to the training unit 202.

The training data may comprise one or more of:
training simulation data generated using system level simulation tools such as radio frequency and physical layer simulators;
training emulation data generated using network emulation tools,
training real network data collected from one or more reference target end devices operable in the wireless network 100 and configured by the training device 103 to report positioning data for selected reference signals.

The training data is labeled data that consist in labeled input/output pairs.

In an embodiment, the training-based compression algorithm, the training-based decompression algorithm, and the training-based distance correction algorithm are artificial neural networks, respectively referred to as compression neural network, decompression neural network, and distance correction neural network.

Exemplary neural networks comprise, without limitation, convolutional neural networks (CNN), deep neural networks (DNN), recurrent neural networks, multilayer perceptrons, and autoencoders.

A neural network is a multi-layer network made up of an input layer and two or more layers that comprise one or more hidden layers and an output layer. Each layer comprises a plurality of artificial neurons or computation nodes.

The artificial neural network is fully connected. This means that each computation node in one layer connects with a certain weight to every computation node in the following layer, i.e. combines input from the connected nodes from a previous layer with a set of weights that either amplify or dampen the input values. The output of each layer is the input of the subsequent layer, starting from the input layer that receives the input data of the artificial neural network. Except the computation nodes comprised in the input layer, the computation nodes comprised in the one or more hidden layers implement an activation function that maps the weighted inputs of the computation nodes in the hidden layers to the output of the computation nodes. The activation function may be one of a linear activation function, a sigmoid function, or a rectified linear unit.

Accordingly, the artificial neural network is associated with a set of model parameters and an activation function, the set of model parameters comprising a weight matrix and a bias vector. The weight matrix comprises real-value coefficients such that each coefficient represents a weight value associated with a connection between two computation nodes that belong to two successive layers.

Accordingly, in this embodiment:
the first set TS⁽¹⁾ of trained parameters comprises a first weight matrix denoted by W⁽¹⁾ and a first bias vector denoted by b⁽¹⁾;
the second set TS⁽²⁾ of trained parameters comprises a second weight matrix denoted by W⁽²⁾ and a second bias vector denoted by b⁽²⁾;
the third set TS⁽³⁾ of trained parameters comprises a third weight matrix denoted by W⁽³⁾ and a third bias vector denoted by b⁽³⁾.

In this embodiment, the training unit 202 performs the joint training of the three training-based algorithms to generate the values of the first weight matrix W⁽¹⁾, the second weight matrix W⁽²⁾, the third weight matrix W⁽³⁾, the first bias vector b⁽¹⁾, the second bias vector b⁽²⁾ and the third bias vector b⁽³⁾ according to the minimization of the loss function.

The joint training of the compression, decompression and distance correction neural networks enables determining and updating the models parameters W⁽¹⁾, b⁽¹⁾, W⁽²⁾, b⁽²⁾, W⁽³⁾, b⁽³⁾ using the training data.

The joint training phase is a global optimization problem performed to jointly adjust the models parameters W⁽¹⁾, b⁽¹⁾, W⁽²⁾, b⁽²⁾, W⁽³⁾, b⁽³⁾ in a way that enables minimizing a training error (also referred to as a prediction error) that quantifies how close the joint architecture comprising the compression, decompression and distance correction neural networks is to the ideal models parameters that provide the best prediction of the estimated distance. The models parameters W⁽¹⁾, b⁽¹⁾, W⁽²⁾, b⁽²⁾, W⁽³⁾, b⁽³⁾ may be initially set to initial parameters, for example generated randomly. These initial parameters are then updated during the training phase and adjusted in a way that enables the joint architecture made of the three compression, decompression, and distance correction artificial neural networks to converge to the best predictions.

In an embodiment, the joint architecture made up of the three neural networks is trained using back-propagation training techniques. Back-propagation training is an iterative process of forward and backward propagations of information by the different layers of the neural networks.

During a first phase (referred to as the forward propagation phase), the joint architecture receives training data that comprises training input values and expected values associated with the training input values, the expected values corresponding to the expected output of the joint architecture when the training input values are fed into the joint architecture as input. As the joint architecture comprises three neural networks implemented in a cascade fashion, the forward propagation phase is performed in a joint way such that the training input data is fed into the compression neural network and the estimated values to be compared to the expected values associated with the training input values are obtained as the output of the distance correction neural network.

Accordingly, during the forward propagation phase, the training input values passes across the compression neural network which generates training compressed positioning reports from the training input values. The training compressed positioning reports are then fed into the decompression neural network which generates training decompressed positioning reports from the training compressed positioning reports. Then reconstructed data from the training decompressed positioning reports are fed into the distance correction neural network which generates training estimated distance as estimated values corresponding to the training data fed into the compression neural network.

The last step of the forward propagation phase is performed by the loss function generation unit 2023 that compares the expected values associated with the training data with the training estimated distance obtained when the training data was passed through the joint architecture. The comparison enables measuring how good/bad the training estimated distance was with respect to the expected values and to update the parameters of the three neural networks with the aim of approaching the training estimated distance values to the expected values such that the training error is near to zero. The training error is estimated using the loss function L(.) based on a gradient procedure that updates the models parameters.

The forward propagation phase is followed with a backward propagation phase during which the models parameters W⁽¹⁾, b⁽¹⁾, W⁽²⁾, b⁽²⁾, W⁽³⁾, b⁽³⁾ are gradually adjusted in reverse order by applying an optimization algorithm until good predictions are obtained and the loss function is minimized. During this phase, the computed training error is propagated backward on the distance correction neural network, the decompression neural network, and the compression neural network starting from the output layer to all the computation nodes of the hidden layers that contribute to the computation of the estimated values. Each computation node receives a fraction of the total training error based on its relative contribution to the output of the neural network. The process is repeated, layer by layer, until all the computation nodes in the three neural networks have received a training error that correspond to their relative contributions to the total training error. Once the training error is spread backward, the weights and the bias vectors are updated by applying an optimization algorithm according to the minimization of the loss function that is averaged over the training set.

Exemplary loss functions comprise, without limitation:
the absolute error function expressed by L(dₜ, \hat{d}ₜ)=|dₜ−\hat{d}ₜ|;
the mean square error (MSE) function expressed by L(dₜ, \hat{d}ₜ)= [symbol] [(dₜ−\hat{d}ₜ)²];
the normalized mean square error function;
the exponential log likelihood function.

Exemplary optimization algorithms used to adjust the models parameters comprise, without limitation, the adaptive moment estimation algorithm (ADAM) that computes adaptive learning rates for each model parameter, the Nesterov accelerated gradient (NAG) algorithm, the stochastic gradient optimization algorithm, and the adaptive learning rate optimization algorithm.

In an embodiment, the training-based compression algorithm and the training-based decompression algorithm form an auto-encoder. The autoencoder is a neural network that learns to copy its input to its output. It comprises an internal hidden layer that describes a code used to represent the input. The autoencoder comprises an encoder that maps the input into the code and a decoder that maps the code to a reconstruction of the input.

In this embodiment, the autoencoder has a given code size denoted by C and comprises the training-based compression algorithm as the encoder and the training-based decompression algorithm as the decoder. The given code size maps to the given compression level according to which the training-based compression algorithm generates the compressed positioning report R_{comp}.

In an embodiment, the given code size C is flexible and is selected from a set of (J≥2) two or more codes sizes denoted by C₁, . . . , C_{J} as a tradeoff between positioning latency and accuracy. For example, small code sizes will reduce the latency of the positioning report but also the accuracy of the final position estimate.

Each code size Cⱼ for j=1, . . . , J maps to a compression level.

In this embodiment, the joint training of the training-based compression, decompression and distance correction algorithms is performed for the two or more compression levels such that for each code size Cⱼ that maps to a compression level, a first set of trained parameters denoted by TSⱼ⁽¹⁾ defining a trained compression algorithm, a second set of trained parameters denoted by TSⱼ⁽²⁾ defining a trained decompression algorithm, and a third set of trained parameters denoted by TSⱼ⁽³⁾ are generated for j=1, . . . , J, i.e. for the two or more code sizes C₁, . . . , C_{J}.

In this embodiment, the training device 103 may transfer the sets of parameters generated for the two or more compression levels to the positioning reports producer 101 and the positioning reports consumer 102 that may deploy one of the sets of parameters for example according to code size specifications.

In application to 5G and beyond networks, the set of code sizes C₁, . . . , C_{J} may be defined at the localization and management function and sent to the positioning reports producer 101 and the positioning reports consumer 102 in the LPP assistance data. The localization management function may request explicitly the use of a specific code size making the positioning reports producer 101 and/or the positioning reports consumer 102 deploy the set of parameters among the two or more sets of parameters received for the two or more compression levels according to the request of the localization and management function.

According to some embodiments, the positioning report comprises data for positioning the target end device 10, the data for positioning the target end device 10 comprising measurements for positioning the target end device 10 or signal features related to the one or more reference signals or raw signal samples comprised in the one or more reference signals S_{ref}:

A measurement for positioning the target end device 10 refers to a measurement that is used for positioning purposes and is computed or estimated from the one or more reference signals S_{ref}. Accordingly, the measurements for positioning the target end device 10 comprise:
positioning measurements that are computed or estimated from one or more positioning reference signals;
measurements that are computed or estimated from one or more reference signals that are not reference positioning signals but reference signals that are used for positioning the target end device 10 (such as mobility and radio resource management reference signals).

Exemplary positioning measurements comprise, without limitation:
time-based measurements such as time of arrival measurements (e.g. downlink time difference of arrival), uplink relative time of arrival, transmitter-receiver time difference, relative time of arrival, multi-cell round trip time measurements, and
angular-based measurements such as multiple antenna beam measurements, downlink angle of departure measurements, uplink angle of arrival measurements, azimuth and zenith of angle of arrival.

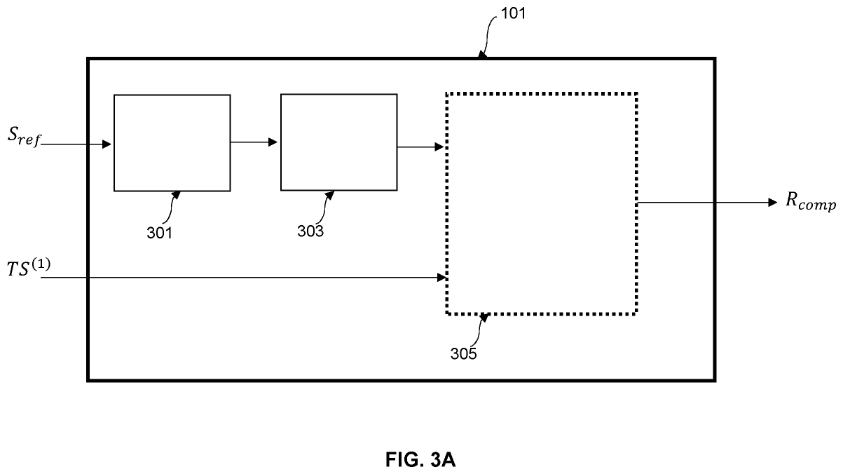

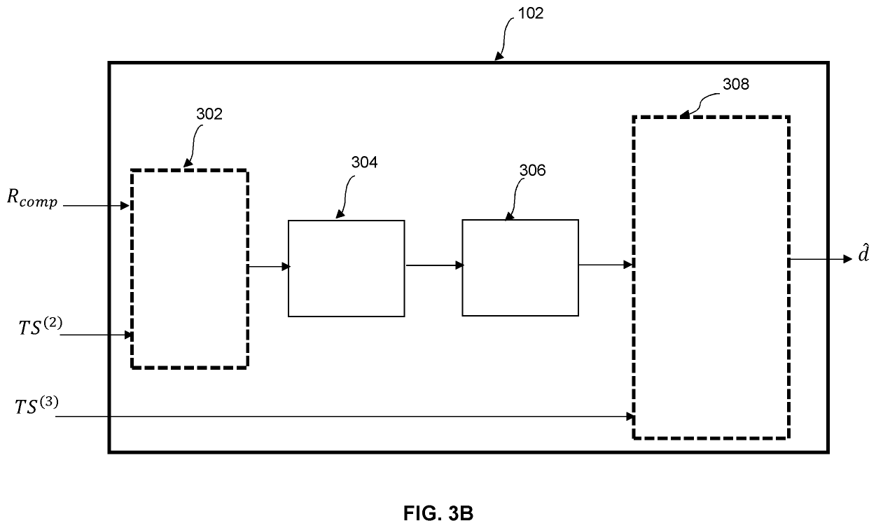

FIG. 3A and FIG. 3B show respectively the structure of the positioning reports producer 101 and the positioning reports consumer 102 in an exemplary embodiment in which the positioning report comprises measurements for positioning the target end device 10. As the training unit 202 comprised in the training device 103 comprises identical structures of the positioning reports producer 101 and the positioning reports consumer 102, the structure of the training device 103 is not illustrated for this embodiment for simplification reasons.

As depicted in FIG. 3A, the positioning reports producer 101 comprises a measurements calculation unit 301 configured to generate estimated measurements given the received one or more reference signals S_{ref} for positioning the target end device 10. For example, the measurements calculation unit 301 generates time of arrival or time difference of arrival measurements given the received one or more reference signals S_{ref}.

The generated measurements are then fed into a decimal to binary converter 303 configured to convert the generated measurements to a format that is suitable for input to the compression unit 305 that implements the training-based compression algorithm defined by the set TS⁽¹⁾ of trained parameters previously received from the training device 103. The decimal to binary converter 303 applies a decimal to binary conversion to the measurements generated by the measurements calculation unit 301.

The signal obtained by the decimal to binary conversion may have a binary column vector representation denoted by x.

The binary column vector is then fed into the compression unit 305 and processed by the training-based compression algorithm to generate the compressed positioning report R_{comp} from the binary column vector x. In this case, the compressed positioning report comprises compressed measurements for positioning the target end device 10.

In an embodiment, the training-based compression algorithm is the encoder part of an autoencoder and is a multi-layer neural network defined by an activation function denoted by σ, a set of trained parameters TS⁽¹⁾={W⁽¹⁾, b⁽¹⁾} comprising a weight matrix W⁽¹⁾ and a bias vector b⁽¹⁾, and a plurality of layers denoted by K layers. According to the multilayer structure, the neural network defines a mapping denoted by fₖ(inₖ, Wₖ⁽¹⁾, bₖ⁽¹⁾) in association with each layer k among the plurality of K such that the mapping maps the input inₖ of the layer k to the output outₖ=fₖ(inₖ, W⁽¹⁾, b⁽¹⁾) using a weight matrix W⁽¹⁾ associated with the layer k and a bias vector bₖ⁽¹⁾ associated with the layer k such that:

$${out}_{k} = {f}_{k} ( {in}_{k} , {W}_{k}^{( 1 )} , {b}_{k}^{( 1 )} ) = σ ( {W}_{k}^{( 1 )} {in}_{k} + {b}_{k}^{( 1 )} ) \qquad ( 1 )$$

The input-weight products performed at the computation nodes of the layer k are represented accordingly by the production function Wₖ⁽¹⁾inₖ between the weight matrix Wₖ⁽¹⁾ and the input inₖ of layer k, these input-weight products are then summed with the bias vector bₖ⁽¹⁾ associated with the layer k and the sum is passed through the activation function σ.

Accordingly, considering the multilayer structure of the compression neural network, the compressed positioning report R_{comp} is generated from the binary column vector x according to the equation given by:

$${R}_{c o m p} = σ ( {W}_{K}^{( 1 )} ( … ( {W}_{2}^{( 1 )} σ ( {W}_{1}^{( 1 )} x + {b}_{1}^{( 1 )} ) + {b}_{2}^{( 1 )} ) … ) + {b}_{K}^{( 1 )} ) \qquad ( 2 )$$

In this embodiment, the compression neural network converts the binary column vector x into a shorter representation of a length corresponding to the code size C of the autoencoder while preserving the relevant features of the binary column vector.

The structure of the positioning reports consumer 102 depicted in FIG. 3B comprises symmetrical processing blocks as the processing blocks implemented in the positioning reports producer 101 in FIG. 3A.

Accordingly, the positioning reports consumer 102 comprises a decompression unit 302 implementing the training-based decompression algorithm defined by the set TS⁽²⁾ of trained parameters previously received from the training device 103. The training-based decompression generates a decompressed positioning report R_{dec} from the received compressed positioning report R_{comp}. In this case, the decompressed positioning report comprises decompressed measurements for positioning the target end device 10.

In an embodiment, the training-based decompression algorithm is the decoder part of an autoencoder and is a multi-layer neural network defined by an activation function denoted by σ, a set of trained parameters TS⁽²⁾={W⁽²⁾, b⁽²⁾} comprising a weight matrix W⁽²⁾ and a bias vector b⁽²⁾, and a plurality of layers denoted by K layers. According to the multilayer structure, the neural network defines a mapping denoted by fₖ(inₖ, W⁽²⁾, b⁽²⁾) in association with each layer k among the plurality of K such that the mapping maps the input inₖ of the layer k to the output outₖ=fₖ(inₖ, W⁽²⁾, b⁽²⁾) using a weight matrix W⁽²⁾ associated with the layer k and a bias vector bₖ⁽²⁾ associated with the layer k such that:

$${out}_{k} = {f}_{k} ( {in}_{k} , {W}_{k}^{( 2 )} , {b}_{k}^{( 2 )} ) = σ ( {W}_{k}^{( 2 )} {in}_{k} + {b}_{k}^{( 2 )} ) \qquad ( 3 )$$

The input-weight products performed at the computation nodes of the layer k are represented accordingly by the production function Wₖ⁽²⁾inₖ between the weight matrix Wₖ⁽²⁾ and the input inₖ of layer k, these input-weight products are then summed with the bias vector bₖ⁽²⁾ associated with the layer k and the sum is passed through the activation function σ.

Accordingly, considering the multilayer structure of the decompression neural network, the decompressed positioning report R_{dec} is generated from the compressed positioning report R_{comp} according to the equation given by:

$${R}_{dec} = σ ( {W}_{K}^{( 2 )} ( … ( {W}_{2}^{( 2 )} σ ( {W}_{1}^{( 2 )} x + {b}_{1}^{( 2 )} ) + {b}_{2}^{( 2 )} ) … ) + {b}_{K}^{( 2 )} ) \qquad ( 4 )$$

The decompressed positioning report R_{dec} is a reconstructed binary column vector x′. It is then fed into a binary to decimal converter 304 that converts the decompressed report x′ into a decimal measurements vector such that the decimal measurements vector comprises reconstructed measurements for positioning the target end device 10.

The reconstructed decimal measurements are then fed into a distance estimation unit 306 configured to generate a distance value denoted by l from the reconstructed decimal measurements.

The generated distance value l is then fed into a distance correction unit 308 that implements a training-based distance correction algorithm to generate an estimated corrected distance denoted by d from the distance value l. The training-based distance correction algorithm returns a corrected estimated distance value \hat{d} by correcting the signal processing-related effects that impact the estimation of the distance at the distance estimation unit 306. Such effects comprise for example radio frequency non-linear effects (e.g. phase noise, RF-BB conversion delays) and RF signal bandwidth.

In an embodiment, the training-based distance correction algorithm is a multi-layer neural network defined by an activation function denoted by σ, a set of trained parameters TS⁽³⁾={W⁽³⁾, b⁽³⁾} comprising a weight matrix W⁽³⁾ and a bias vector b⁽³⁾, and a plurality of layers denoted by K layers. According to the multilayer structure, the neural network defines a mapping denoted by fₖ(inₖ, W⁽³⁾, bₖ⁽³⁾) in association with each layer k among the plurality of K such that the mapping maps the input inₖ of the layer k to the output outₖ=fₖ(inₖ, Wₖ⁽³⁾, bₖ⁽³⁾) using a weight matrix Wₖ⁽³⁾ associated with the layer k and a bias vector bₖ⁽³⁾ associated with the layer k such that:

$${out}_{k} = {f}_{k} ( {in}_{k} , {W}_{k}^{( 3 )} , {b}_{k}^{( 3 )} ) = σ ( {W}_{k}^{( 3 )} {in}_{k} + {b}_{k}^{( 3 )} ) \qquad ( 5 )$$

The input-weight products performed at the computation nodes of the layer k are represented accordingly by the production function Wₖ⁽³⁾inₖ between the weight matrix Wₖ⁽³⁾ and the input inₖ of layer k, these input-weight products are then summed with the bias vector bₖ⁽³⁾ associated with the layer k and the sum is passed through the activation function σ.

Accordingly, considering the multilayer structure of the distance correction neural network, the estimated corrected distance d is generated from the distance value l according to the equation given by:

$$\hat{d} = σ ( {W}_{K}^{( 3 )} ( … ( {W}_{2}^{( 3 )} σ ( {W}_{1}^{( 3 )} x + {b}_{1}^{( 3 )} ) + {b}_{2}^{( 3 )} ) … ) + {b}_{K}^{( 3 )} ) \qquad ( 6 )$$

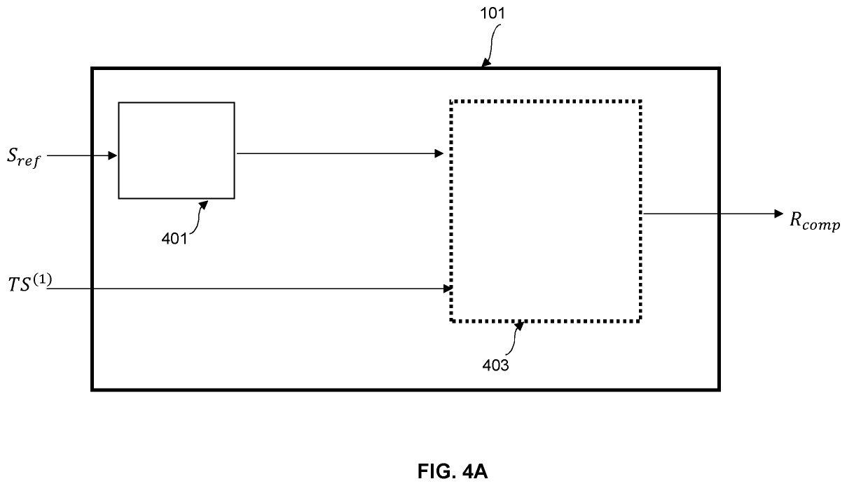

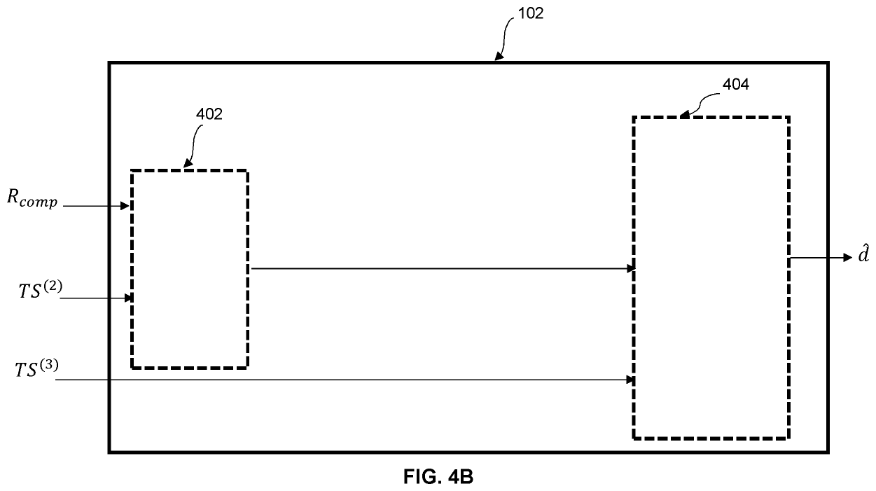

FIG. 4A and FIG. 4B show respectively exemplary structures of the positioning reports producer 101 and the positioning reports consumer 102 in an exemplary embodiment in which the positioning report comprises signal features related to the one or more reference signals S_{ref}. As the training unit 202 comprised in the training device 103 comprises identical structures of the positioning reports producer 101 and the positioning reports consumer 102, the structure of the training device 103 is not illustrated for this embodiment for simplification reasons.

In this embodiment, the positioning reports producer 101 comprises a features extraction unit 401 configured to extract a set of signal characteristics from the one or more reference signals S_{ref}. For example, the features extraction unit 401 implements principal component analysis (PCA), a variant of a Fourier Transform (e.g. Fast Fourier Transform or short FFT). The features extraction unit 401 applies a transformation function denoted by F that generates a features vector denoted by x such that x=F(S_{ref}).

The features vector x is then fed into a compression unit 403 that implements the training-based compression algorithm defined by the set TS⁽¹⁾ of trained parameters that generates a compressed positioning report R_{comp} from the features signal x.

In an embodiment in which the training-based compression algorithm is the encoder part of an autoencoder and is a K layers neural network defined by an activation function denoted by σ, a set of trained parameters TS(1)={W⁽¹⁾, b⁽¹⁾} comprising a weight matrix W⁽¹⁾ and a bias vector b⁽¹⁾, and K layers, the compressed positioning report R_{comp} is generated as a function of the features signal x according to:

$${R}_{c o m p} = σ ( {W}_{K}^{( 1 )} ( … ( {W}_{2}^{( 1 )} σ ( {W}_{1}^{( 1 )} x + {b}_{1}^{( 1 )} ) + {b}_{2}^{( 1 )} ) … ) + {b}_{K}^{( 1 )} ) \qquad ( 7 )$$

The structure of the positioning reports consumer 102 depicted in FIG. 4B comprises a decompression unit 402 that implements the training-based decompression algorithm configured to receive the compressed positioning report R_{comp} from the positioning reports producer 101 and the second set TS⁽²⁾ of trained parameters from the training device 103. The training-based decompression algorithm generates a decompressed positioning report R_{dec} from the received compressed positioning report R_{comp}. In this case, the decompressed positioning report comprises decompressed signal features related to the one or more reference signals S_{ref}. The decompressed positioning report is thus a reconstruction or similarly an estimation of the features vector x.

In an embodiment in which the training-based decompression algorithm is the decoder part of an autoencoder and is a K layers neural network defined by an activation function denoted by σ, a set of trained parameters TS(2)={W⁽²⁾, b⁽²⁾} comprising a weight matrix W⁽²⁾ and a bias vector b⁽²⁾, and K layers, the decompressed positioning report R_{dec} is generated as a function of the compressed positioning report R_{comp} according to:

$${R}_{dec} = σ ( {W}_{K}^{( 2 )} ( … ( {W}_{2}^{( 2 )} σ ( {W}_{1}^{( 2 )} {R}_{comp} + {b}_{1}^{( 2 )} ) + {b}_{2}^{( 2 )} ) … ) + {b}_{K}^{( 2 )} ) \qquad ( 8 )$$

The decompressed positioning report is then fed into a distance correction unit 404 configured to receive the set of trained parameters TS⁽³⁾ from the training device 103 and to generate an estimated distance \hat{d} from the decompressed positioning report R_{dec} by running the training-based distance correction algorithm.

In an embodiment in which the training-based distance correction algorithm a K layers neural network defined by an activation function denoted by σ, a set of trained parameters TS⁽³⁾={W⁽³⁾, b⁽³⁾} comprising a weight matrix W⁽³⁾ and a bias vector b⁽³⁾, and K layers, the estimated distance \hat{d} is generated from the decompressed positioning report R_{dec} according to:

$$\hat{d} = σ ( {W}_{K}^{( 3 )} ( … ( {W}_{2}^{( 3 )} σ ( {W}_{1}^{( 3 )} {R}_{comp} + {b}_{1}^{( 3 )} ) + {b}_{2}^{( 3 )} ) … ) + {b}_{K}^{( 3 )} ) \qquad ( 9 )$$

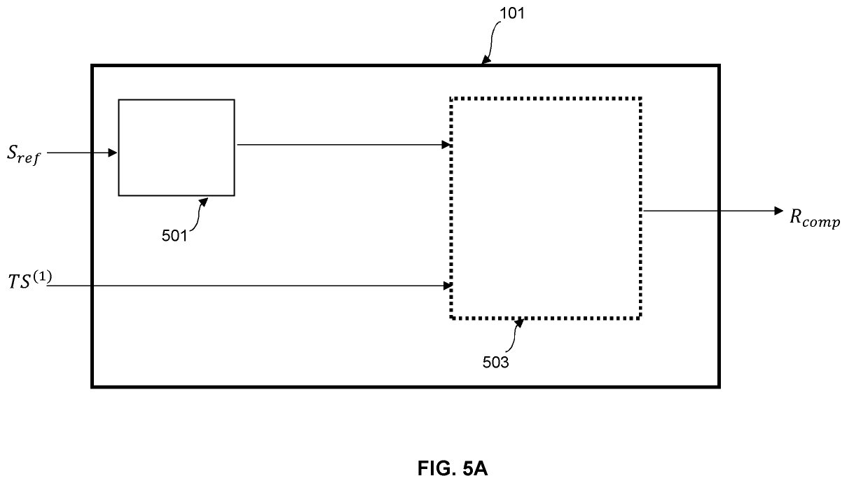

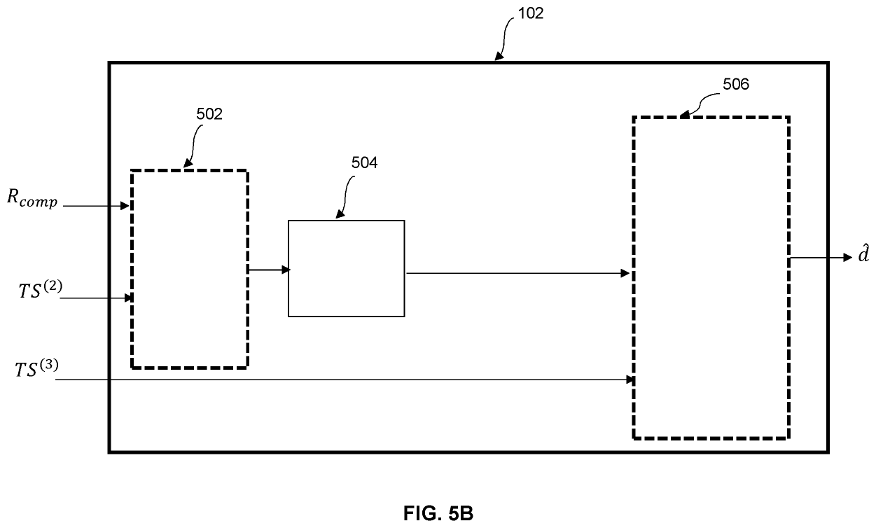

FIG. 5A and FIG. 5B show respectively exemplary structures of the positioning reports producer 101 and the positioning reports consumer 102 in an exemplary embodiment in which the positioning report comprises the raw signal samples comprised in the one or more reference signals S_{ref}. As the training unit 202 comprised in the training device 103 comprises identical structures of the positioning reports producer 101 and the positioning reports consumer 102, the structure of the training device 103 is not illustrated for this embodiment for simplification reasons.

In this embodiment, the positioning reports producer 101 comprises a converter 501 configured to perform complex-to-real conversion to convert each reference signal S_{ref} into a raw samples vector denoted by x such that the raw samples vector has a length that is the double of the length of the reference signal S_{ref} and that the raw samples vector comprises the real and imaginary parts of the samples comprised in the reference signal S_{ref}, i.e. x=[Re(S_{ref}),Im(S_{ref})] with Re(.) and Im(.) designating respectively the real and imaginary parts of an input value.

The raw samples vector is then fed into a compression unit 503 configured to receive the set TS⁽¹⁾ from the training device 103 and to implement the training-based compression algorithm to generate a compressed positioning report R_{comp} from the raw samples vector x. In this case, the compressed positioning report comprises compressed raw samples of the one or more reference signals S_{ref}.

In an embodiment in which the training-based compression algorithm is the encoder part of an autoencoder and is a K layers neural network defined by an activation function denoted by σ, a set of trained parameters TS⁽¹⁾={W⁽¹⁾, b⁽¹⁾} comprising a weight matrix W⁽¹⁾ and a bias vector b⁽¹⁾, and K layers, the compressed positioning report R_{comp} is generated as a function of the raw samples vector x according to:

$${R}_{c o m p} = σ ( {W}_{K}^{( 1 )} ( … ( {W}_{2}^{( 1 )} σ ( {W}_{1}^{( 1 )} x + {b}_{1}^{( 1 )} ) + {b}_{2}^{( 1 )} ) … ) + {b}_{K}^{( 1 )} ) \qquad ( 10 )$$

The structure of the positioning reports consumer 102 depicted in FIG. 5B comprises a decompression unit 502 that implements the training-based decompression algorithm configured to receive the compressed positioning report R_{comp} from the positioning reports producer 101 and the second set TS⁽²⁾ of trained parameters from the training device 103. The training-based decompression algorithm generates a decompressed positioning report R_{dec} from the received compressed positioning report R_{comp}. In this case, the decompressed positioning report comprises decompressed raw samples comprised in the one or more reference signals S_{ref}. The decompressed positioning report is thus a reconstruction or similarly an estimation of the raw samples vector x.

In an embodiment in which the training-based decompression algorithm is the decoder part of an autoencoder and is a K layers neural network defined by an activation function denoted by σ, a set of trained parameters TS(2)={W⁽²⁾, b⁽²⁾} comprising a weight matrix W⁽²⁾ and a bias vector b⁽²⁾, and K layers, the decompressed positioning report R_{dec} is generated as a function of the compressed positioning report R_{comp} according to:

$${R}_{dec} = σ ( {W}_{K}^{( 2 )} ( … ( {W}_{2}^{( 2 )} σ ( {W}_{1}^{( 2 )} {R}_{comp} + {b}_{1}^{( 2 )} ) + {b}_{2}^{( 2 )} ) … ) + {b}_{K}^{( 2 )} ) \qquad ( 11 )$$

The decompressed positioning report is then fed into a distance estimation unit 504 configured to generate a distance value denoted by l from the reconstructed raw samples vector.

The generated distance value l is then fed into a distance correction unit 506 configured to receive the third set TS⁽³⁾ of trained parameters from the training device 103 and to implement a training-based distance correction algorithm to generate an estimated corrected distance denoted by d from the distance value l.

In an embodiment in which the training-based distance correction algorithm is a K layers neural network defined by an activation function denoted by σ, a set of trained parameters TS⁽³⁾={W⁽³⁾, b⁽³⁾} comprising a weight matrix W⁽³⁾ and a bias vector b⁽³⁾, and K layers, the estimated corrected distance d is generated as a function of the distance value (according to:

$$\hat{d} = σ ( {W}_{K}^{( 3 )} ( … ( {W}_{2}^{( 3 )} σ ( {W}_{1}^{( 3 )} l + {b}_{1}^{( 3 )} ) + {b}_{2}^{( 3 )} ) … ) + {b}_{K}^{( 3 )} ) \qquad ( 12 )$$

In an embodiment in which the positioning measurements are time of arrival measurements, the distance value l may be generated by computing an estimated time of arrival value denoted by t and converting the estimated time of arrival value to the distance value (such that l=\hat{τ}c₀ with c₀=3.10⁸ ms⁻¹ designating the speed of light.

The training data generated by the training data generation unit 201 depend on the type of data processed by the trainable compression algorithm. For example, in the embodiment in which the positioning report comprises measurements values, the training data comprises training measurements values (e.g. training time of arrival estimates) generated for example for different training signal-to-noise ratios and for different training bandwidths. For example, the training signal-to-noise ratios may be drawn from a uniform distribution in an interval lower bounded by a lower-bound signal-to-noise ratio value and upper bounded by an upper-bound signal-to-noise ratio value. Similarly, the training data may be generated/collected over different training bandwidths, drawn for example in a uniform distribution in a interval that is lower bounded by a lower bound bandwidth value and upper bounded by an upper bound bandwidth value.

Further, the training measurements may be collected from target end devices distributed uniformly inside a given cell such that the measurements are balanced and the corresponding training distance values are drawn from a uniform distribution in an interval that is lower bounded by a lower bound distance value and upper bounded by an upper bound distance value.

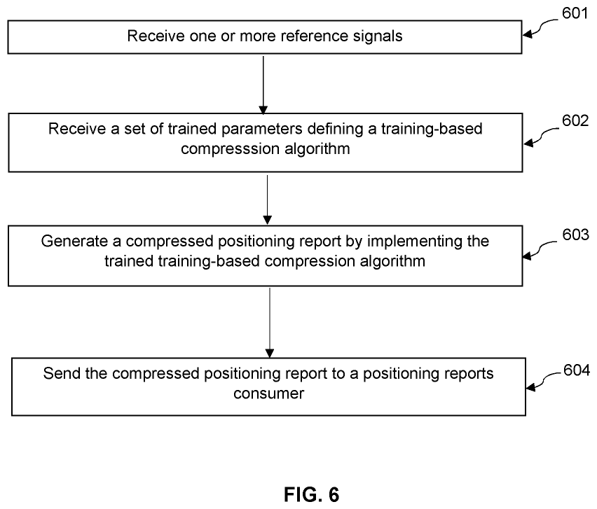

FIG. 6 is a flowchart illustrating a method for generating and sending a compressed positioning report, according to some embodiments. The method may be implemented at the positioning reports producer 101.

At step 601, one or more reference signals S_{ref} for positioning a target device 10 are received. Depending on whether the positioning is uplink or downlink positioning, the one or more reference signals are either received from the target end device 10 or from the network device 11.

At step 602, a first set TS⁽¹⁾ of trained parameters defining a training-based compression algorithm are received from a training device 103.

At step 603, a compressed positioning report R_{com} is generated by implementing the training-based compression algorithm that takes as input the one or more reference signals S_{ref} for positioning the target device 10 and generates as output the compressed positioning report R_{com}.

At step 604, the compressed positioning report R_{com} is sent to a positioning reports consumer 102.

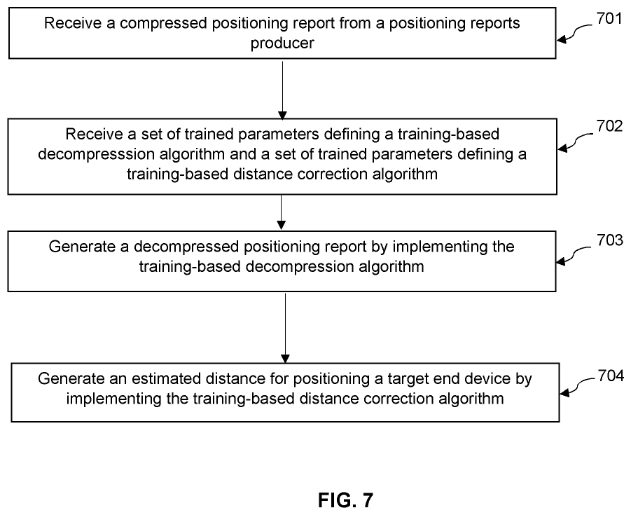

FIG. 7 is a flowchart illustrating a method for generating an estimated distance for positioning the target end device 10, according to some embodiments.

At step 701, a compressed positioning report R_{com} is received from a positioning reports producer 101.

At step 702, a second set TS⁽²⁾ of trained parameters defining a training-based decompression algorithm and a third set TS⁽³⁾ of trained parameters defining a training-based distance correction algorithm are received from a training device 103.

At step 703, a decompressed positioning report R_{dec} is generated by implementing the training-based decompression algorithm that takes as input the compressed positioning report R_{com} and generates as output the decompressed positioning report R_{dec}.

At step 704, an estimated distance d for positioning the target end device 10 is generated by implementing the training-based distance correction algorithm that takes as input data reconstructed from the decompressed positioning report and generates as output the estimated distance \hat{d}.

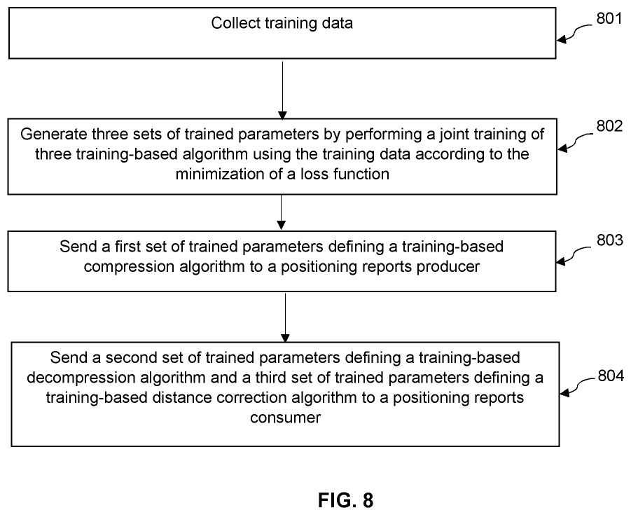

FIG. 8 is a flowchart illustrating a method for joint training three training-based algorithms.

As step 801, training data is collected. At step 802, three sets of trained parameters are generated by performing a joint training of three training-based algorithms using the training data according to the minimization of a loss function. At step 803, the first set of trained parameters defining a training-based compression algorithm is sent to a positioning reports producer 101. At step 804, the second set of trained parameters defining a training-based decompression algorithm and a third set of trained parameters defining a training-based distance correction algorithm are sent to a positioning reports consumer 102.

It should be appreciated by those skilled in the art that any functions, engines, block diagrams, flow diagrams, state transition diagrams and/or flowcharts herein represent conceptual views of illustrative circuitry embodying the principles of the invention. Similarly, it will be appreciated that any flow charts, flow diagrams, state transition diagrams, pseudo code, and the like represent various processes which may be substantially represented in computer readable medium and so executed by a computer or apparatus, whether such computer or processor is explicitly shown.

Each described computation function, block, step can be implemented in hardware, software, firmware, middleware, microcode, or any suitable combination thereof. If implemented in software, the computation functions, blocks of the block diagrams and/or flowchart illustrations can be implemented by computer program instructions/software code, which may be stored or transmitted over a computer-readable medium, or loaded onto a general purpose computer, special purpose computer or other programmable processing apparatus and/or system to produce a machine, such that the computer program instructions or software code which execute on the computer or other programmable apparatus, create the means for implementing the functions described herein.

When implemented in software, firmware, middleware or microcode, the program code or code segments to perform the necessary tasks may be stored in a machine or computer readable medium such as a computer readable storage medium. When implemented in software, a processor or processors will perform the necessary tasks. For example, as mentioned above, according to one or more example embodiments, at least one memory may include or store computer program code, and the at least one memory and the computer program code may be configured to, with at least one processor, cause an apparatus to perform the necessary tasks. Additionally, the processor, memory and example algorithms, encoded as computer program code, serve as means for providing or causing performance of operations discussed herein.

For example, the functions described here for positioning reports producer, the positioning reports consumer and the training device may be performed by a corresponding apparatus.

In the present description, block denoted as “means configured to” perform a certain function or “means for” performing a certain function shall be understood as functional blocks comprising circuitry that is adapted for performing or configured to perform a certain function. A means being configured to perform a certain function does, hence, not imply that such means necessarily is performing said function (at a given time instant). Moreover, any entity described herein as “means”, may correspond to or be implemented as “one or more modules”, “one or more devices”, “one or more units”, etc. When provided by a processor, the functions may be provided by a single dedicated processor, by a single shared processor, or by a plurality of individual processors, some of which may be shared. Moreover, explicit use of the term “processor” or “controller” should not be construed to refer exclusively to hardware capable of executing software, and may implicitly include, without limitation, digital signal processor (DSP) hardware, network processor, application specific integrated circuit (ASIC), field programmable gate array (FPGA), read only memory (ROM) for storing software, random access memory (RAM), and non-volatile storage. Other hardware, conventional or custom, may also be included. Their function may be carried out through the operation of program logic, through dedicated logic, through the interaction of program control and dedicated logic, or even manually, the particular technique being selectable by the implementer as more specifically understood from the context.

As used in this application, the term “circuit” or “circuitry” may refer to one or more or all of the following:
(a) hardware-only circuit implementations (such as implementations in only analog and/or digital circuitry) and
(b) combinations of hardware circuits and software, such as (as applicable): (i) a combination of analog and/or digital hardware circuit(s) with software/firmware and (ii) any portions of hardware processor(s) with software (including digital signal processor(s)), software, and memory(ies) that work together to cause an apparatus, such as a mobile phone or server, to perform various functions); and
(c) hardware circuit(s) and or processor(s), such as a microprocessor(s) or a portion of a microprocessor(s), that requires software (e.g., firmware) for operation, but the software may not be present when it is not needed for operation.”

This definition of “circuit” or “circuitry” applies to all uses of this term in this application, including in any claims. As a further example, as used in this application, the term circuitry also covers an implementation of merely a hardware circuit or processor (or multiple processors) or portion of a hardware circuit or processor and its (or their) accompanying software and/or firmware. The term circuitry also covers, for example and if applicable to the particular claim element, an integrated circuit for a network element or network node or any other computing device or network device. The term circuitry may cover digital signal processor (DSP) hardware, network processor, application specific integrated circuit (ASIC), field programmable gate array (FPGA), etc.

The “circuit” or “circuitry” may be or include, for example, hardware, programmable logic, a programmable processor that executes software or firmware, and/or any combination thereof (e.g. a processor, control unit/entity, controller) to execute instructions or software and control transmission and receptions of signals, and a memory to store data and/or instructions.

The “circuit” or “circuitry” may also make decisions or determinations, generate frames, packets or messages for transmission, decode received frames or messages for further processing, and other tasks or functions described herein. The circuitry may control transmission of signals or messages over a radio network, and may control the reception of signals or messages, etc., via a radio network (e.g., after being down-converted by radio transceiver, for example).

As disclosed herein, the term “storage medium,” “computer readable storage medium” or “non-transitory computer readable storage medium” may represent one or more devices for storing data, including read only memory (ROM), random access memory (RAM), magnetic RAM, core memory, magnetic disk storage mediums, optical storage mediums, flash memory devices and/or other tangible machine-readable mediums for storing information. The term “computer-readable medium” may include, but is not limited to, portable or fixed storage devices, optical storage devices, and various other mediums capable of storing, containing or carrying instruction(s) and/or data.

The methods and devices described herein may be implemented by various means. For example, these techniques may be implemented in hardware, software, or a combination thereof. For a hardware implementation, the processing elements of the different network elements operating in the wireless network 1 can be implemented for example according to a hardware-only configuration (for example in one or more FPGA, ASIC, or VLSI integrated circuits with the corresponding memory) or according to a configuration using both VLSI and Digital Signal Processor (DSP).

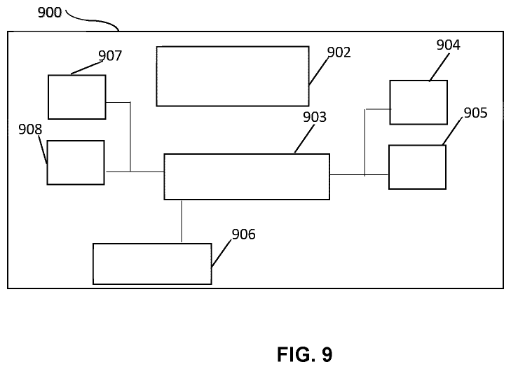

FIG. 9 is a block diagram representing an exemplary hardware/software architecture of a network entity 900 operating in the wireless network 1 such as the network device 11, the target end device 10 and the training device 103, according to some embodiments. As illustrated, the architecture may include various computing, processing, storage, communication, and displaying units comprising:
communication circuitry comprising a transceiver 902 (e.g. wireless or optical transceiver) configured to connect the network entity 900 to corresponding links in the wireless network 1, and to ensure transmission/reception of data and/or signals. The communication circuitry may support various network and air interface such as wired, optical fiber, and wireless networks;
a processing unit 903 configured to execute the computer-executable instructions to run the methods and algorithms according to the various embodiments and perform the various required functions of the network entity such as positioning reports compression and decompression, training of the training-based algorithms; and any functionalities required to enable the network entity 900 to operate in the wireless network according to the various embodiments. The processing unit 902 may be a general purpose processor, a special purpose processor, a DSP, a plurality of microprocessors, a controller, a microcontroller, an ASIC, an FPGA circuit, any type of integrated circuit, and the like;
a power source 904 that may be any suitable device providing power to the network entity 900 such as dry cell batteries, solar cells, and fuel cells;
a localization unit 905 such as a GPS chipset implemented in applications that require information indicating the location of the network entity 900;
a storage unit 906 possibly comprising a random access memory (RAM) or a read-only memory used to store data (e.g. training data) and any data required to perform the functionalities of the network entity 900 according to the embodiments;
Input peripherals 907;
Output peripherals 908 comprising communication means such as displays enabling for example man-to-machine interaction between the network entity 900 and the wireless network 1 operator for example for configuration and/or maintenance purposes.

The architecture of the device 900 may further comprise one or more software and/or hardware units configured to provide additional features, functionalities and/or network connectivity.

Furthermore, the methods described herein can be implemented by computer program instructions supplied to the processor of any type of computer to produce a machine with a processor that executes the instructions to implement the functions/acts specified herein. These computer program instructions may also be stored in a computer-readable medium that can direct a computer to function in a particular manner. To that end, the computer program instructions may be loaded onto a computer to cause the performance of a series of operational steps and thereby produce a computer implemented process such that the executed instructions provide processes for implementing the functions specified herein.

For example, the program comprises instructions stored on the computer-readable storage medium that, when executed by a processor, cause the processor to:
receive one or more reference signals for positioning a target end device;
receive, from a training device, a set of trained parameters defining a training-based compression algorithm, the set of trained parameters being obtained by a joint training of a training-based compression algorithm and one or more training-based algorithms implemented in a positioning reports consumer;
generate a compressed positioning report by implementing the training-based compression algorithm, the training-based compression algorithm taking as input data derived from the one or more reference signals and generating as output the compressed positioning report;
send the compressed positioning report to the positioning reports consumer.

For example, the program comprises instructions stored on the computer-readable storage medium that, when executed by a processor, cause the processor to:
receive a compressed positioning report from a positioning reports producer;
receive, from a training device, a set of trained parameters defining a training-based decompression algorithm and a set of trained parameters defining a training-based distance correction algorithm, the sets of trained parameters being obtained by a joint training of the training-based decompression algorithm, the training-based distance correction algorithm and a training-based algorithm implemented in the positioning reports producer;
generate a decompressed positioning report by implementing the training-based decompression algorithm, the training-based decompression algorithm taking as input the compressed positioning report and generating as output the decompressed positioning report;
generate an estimated distance for positioning a target device by implementing the training-based distance correction algorithm, the estimated distance designating a distance separating the target device and a localization server, the training-based distance correction algorithm taking as input reconstructed data derived from the decompressed positioning report and generating as output the estimated distance.

For example, the program comprises instructions stored on the computer-readable storage medium that, when executed by a processor, cause the processor to generate
a first set of trained parameters defining a training-based compression algorithm;
a second set of trained parameters defining a training-based decompression algorithm;
a third set of trained parameters defining a training-based distance correction algorithm;
the first set of trained parameters, the second set of trained parameters and the third set of trained parameters being generated by performing a joint training of the training-based compression, decompression, and distance correction algorithms using training data and according to the minimization of a loss function.

The subject matter of the present disclosure includes all novel and non-obvious combinations and sub-combinations of the various processes, systems and configurations, and other features, functions, acts, and/or properties disclosed herein, as well as any and all equivalents thereof.

1. A positioning reports producer comprising:
a processor configured to:
receive one or more reference signals for positioning a target end device;
receive a set of trained parameters defining a training-based compression algorithm from a training device, the set of trained parameters being obtained by a joint training of the training-based compression algorithm and one or more training-based algorithms implemented in a positioning reports consumer;
generate a compressed positioning report by running the training-based compression algorithm, the training-based compression algorithm taking as input data derived from the one or more reference signals and generating as output the compressed positioning report; and
send the compressed positioning report to the positioning reports consumer.

2. A positioning reports consumer comprising:
a processor configured to:
receive a compressed positioning report from a positioning reports producer (101);
receive, from a training device, a set of trained parameters defining a training-based decompression algorithm and a set of trained parameters defining a training-based distance correction algorithm, the sets of trained parameters being obtained by a joint training of the training-based decompression algorithm, the training-based distance correction algorithm and a training-based compression algorithm implemented in the positioning reports producer;
generate a decompressed positioning report by running the training-based decompression algorithm, the training-based decompression algorithm taking as input the compressed positioning report and generating as output the decompressed positioning report; and
generate an estimated distance for positioning a target end device by running the training-based distance correction algorithm, the estimated distance designating a distance separating the target end device and a transmitter or a receiver of one or more reference signals for positioning the target end device, the training-based distance correction algorithm taking as input reconstructed data derived from the decompressed positioning report and generating as output the estimated distance.

3. A training device comprising:
a processor configured to generate:
a first set of trained parameters defining a training-based compression algorithm;
a second set of trained parameters defining a training-based decompression algorithm;
a third set of trained parameters defining a training-based distance correction algorithm:
wherein the first set of trained parameters, the second set of trained parameters and the third set of trained parameters being generated by performing a joint training of the compression, decompression and the distance correction training-based algorithms using training data and according to a minimization of a loss function.

4. The training device of claim 3, wherein
performing the joint training of the compression, decompression and distance correction training-based algorithms comprises jointly:
training a training-based compression algorithm to generate a training compressed positioning report from data derived from one or more training reference signals for positioning a training target end device, for a given training compression level;
training a training-based decompression algorithm to generate a training decompressed positioning report from the training compressed positioning report;
training a training-based distance correction algorithm to generate a training estimated distance for positioning the training target end device from reconstructed data derived from the training decompressed positioning report; and
computing a training distance estimation error by applying the loss function to the training estimated distance and a training real distance separating the training target end device from a training transmitter or a training receiver of the one or more training reference signals.

5. The training device of claim 4, wherein the training-based compression algorithm and the training-based decompression algorithm form an autoencoder of a given code size that maps to a given compression level, the autoencoder comprising the training-based compression algorithm as an encoder and the training-based decompression algorithm as a decoder.

6. The training device of claim 5, wherein the given code size is selected from a set of two or more code sizes as a tradeoff between positioning latency and accuracy.

7. The training device of claim 6, wherein the two or more code sizes map to two or more compression levels, the joint training being performed for the two or more compression levels, the first set of trained parameters, the second set of trained parameters, and the third set of trained parameters being generated for the two or more code sizes.

8. The training device of claim 3, wherein the processor is configured to send the first set of trained parameters to a positioning reports producer and send the second set of trained parameters and the third set of trained parameters to a positioning reports consumer.

9-14. (canceled)

15. A method comprising:
generating
a first set of trained parameters defining a training-based compression algorithm;
a second set of trained parameters defining a training-based decompression algorithm;
a third set of trained parameters defining a training-based distance correction algorithm,
wherein the first set of trained parameters, the second set of trained parameters and the third set of trained parameters being generated by performing a joint training of the compression, decompression and distance correction training-based algorithms using training data and according to a minimization of a loss function.

16. The method of claim 15, wherein the joint training of the compression, decompression and distance correction training-based algorithms comprises jointly:
training a training-based compression algorithm to generate a training compressed positioning report from data derived from one or more training reference signals for positioning a training target end device, for a given training compression level;
training a training-based decompression algorithm to generate a training decompressed positioning report from the training compressed positioning report;
training a training-based distance correction algorithm to generate a training estimated distance for positioning the training target end device from reconstructed data derived from the training decompressed positioning report; and
computing a training distance estimation error by applying the loss function to the training estimated distance and a training real distance separating the training target end device from a training transmitter or a training receiver of the one or more training reference signals.

17. The method of claim 16, wherein the training-based compression algorithm and the training-based decompression algorithm form an autoencoder of a given code size that maps to a given compression level, the autoencoder comprising the training-based compression algorithm as an encoder and the training-based decompression algorithm as a decoder.

18. The method of claim 17, wherein the given code size is selected from a set of two or more code sizes as a tradeoff between positioning latency and accuracy.

19. The method of claim 18, wherein the two or more code sizes map to two or more compression levels, the joint training being performed for the two or more compression levels, the first set of trained parameters, the second set of trained parameters, and the third set of trained parameters being generated for the two or more code sizes.

20. The method of claim 15, comprising sending the first set of trained parameters to a positioning reports producer and sending the second set of trained parameters and the third set of trained parameters to a positioning reports consumer.
